(19) United States
(12) Patent Application Publication
(10) Pub. No.: US 2008/0017966 A1
(43) Pub. Date: Jan. 24, 2008

(54) Pillar Bump Package Technology

(75) Inventors: Richard K. Williams, Cupertino, CA (US); Allen Lam, Fremont, CA (US); Keng Hung Lin, Chupei City (TW)

Correspondence Address: ADVANCED ANALOGIC TECHNOLOGIES, 830 EAST ARQUES AVE, SUNNYVALE, CA, 94085, US

(73) Assignee: ADVANCED ANALOGIC TECHNOLOGIES, INC., Sunnyvale, CA (US)

(21) Appl. No.: 11/696,172

(22) Filed: Apr. 3, 2007

Related U.S. Application Data
(63) Continuation-in-part of application No. 11/381,292, filed on May 2, 2006.

(51) Int. Cl. H01L 23/48; H01L 21/02; H01L 23/02

(52) U.S. Cl. 257/686; 257/692; 438/109; 257/E23.021; 257/E23.079; 257/E21.705

(57) ABSTRACT

A semiconductor product includes a die and leadframe included in a package made of plastic or other insulating material. The die and leadframe are dimensioned so that they overlap in at least one location. One or more pillar bumps, formed from as a cylindrical conductive base topped with a solder bump are used to interconnect the leadframe and die in the region of overlap. The pillar bumps perform several purposes including: electrical connection between the leadframe and die, support for the die during packaging and conduction of heat away from the die.

### BACKGROUND OF THE INVENTION

U.S. patent application Ser. No. 11/381,292 (incorporated in this document by reference) discloses a package technology for semiconductor products that reduces electrical parasitics. The package technology provides an interconnection method referred to as “bump-on-leadframe” or BOL. A typical implementation of a semiconductor product that uses the BOL method includes a leadframe and a die both included in a plastic package. Unlike prior art, where wires are used to interconnect the leadframe and die, the BOL method uses “bumps” made out of silver or other conducting material to interconnect the leadframe and die.

In its simplest form, the leadframe consists of a series of leads that project from one or more sides of the package. Inside the package, each lead extends to overlap some portion of the die. A bump or ball, made of a conductive material such as silver, is positioned between each lead and the die in the region of overlap. The bumps perform several different functions, including: 1) they form the electrical connection between the leads and the die, 2) they support the die during packaging, and 3) they conduct heat away from the die.

In a typical implementation, the die is positioned below the leads. In other words, this means that the leads extend over or above the die to create the required regions of overlap. Alternately, the die may be position above the leads with the leads extending under the die. This flexibility also means that two separate die may be included: one above and one below the leadframe.

In some implementations, it may be desirable or necessary for one or more leads to be electrically isolated from the die. When BOL is used, this is typically accomplished by omitting the bump between those leads and the die. Alternately, the die may be fabricated to be non-conducting at the relevant locations.

The BOL method may be used in combination with traditional interconnection methods such as wire bonding. In some cases, this means that a single die may be attached to the leadframe using a combination of wire bonds and bumps. In other cases, where a single package includes multiple dice, some die may be connected using bumps while others are connected using traditional techniques such as wire bonds.

### SUMMARY OF THE INVENTION

To alleviate the deficiencies of conventional bond wire packages, the current invention provides an interconnection method referred to as “pillar bump-on-leadframe” or PBOL. A typical implementation of a semiconductor product that uses the PBOL method includes a leadframe and a die both included in a plastic package. Unlike prior art, where wires are used to interconnect the leadframe and die, the PBOL method uses “pillar bumps” to interconnect the leadframe and die. Each pillar bump has a cylindrical (or substantially cylindrical) base section. On one end of the base section, a solder bump or ball is attached.

In its simplest form, the leadframe consists of a series of leads that project from one or more sides of the package. Inside the package, each lead extends to overlap some portion of the die. A pillar bump is positioned between each lead and the die in the region of overlap. The base section of each pillar bump is connected to the die and the pillar bump portion is in contact with one of the leads.

The pillar bumps perform several different functions, including: 1) they form the electrical connection between the leads and the die, 2) they support the die during packaging, and 3) they conduct heat away from the die.

In a typical implementation, the die is positioned below the leads. In other words, this means that the leads extend over or above the die to create the required regions of overlap. Alternately, the die may be position above the leads with the leads extending under the die. This flexibility also means that two separate die may be included: one above and one below the leadframe.

In some implementations, it may be desirable or necessary for one or more leads to be electrically isolated from the die. When PBOL is used, this is typically accomplished by omitting the pillar bump between those leads and the die. Alternately, the die may be fabricated to be non-conducting at the relevant locations.

The PBOL method may be used in combination with traditional interconnection methods such as wire bonding. In some cases, this means that a single die may be attached to the leadframe using a combination of wire bonds and pillar bumps. In other cases, where a single package includes multiple dice, some die may be connected using pillar bumps while others are connected using traditional techniques such as wire bonds.

The PBOL technique may be used to produce a range of innovative single die and multi-die semiconductor products. One example is a two die implementation of a synchronous Buck converter. For this implementation, a silicon controller IC is included as a first die and a silicon MOSFET push-pull power stage is included as a second die. The power stage includes a high-side power MOSFET, which may be a P-channel or N-channel device, and a low-side N-channel MOSFET. The controller IC includes appropriate buffers to drive the high and low-side switches. The buffers are driven, in turn by a PFM/PFM control circuit and a break-before-make (BBM) circuit.

One possible variation of the Buck converter just described replaces the silicon MOSFET die with a MESFET based power stage. The MESFET power stage includes a high-side switch and a low-side switch both implemented as enhancement mode N-channel MESFET devices. Because the high-side switch is necessarily an N-channel device (P-channel MESFET devices are difficult to manufacture and are not commercially available), its gate buffer must “float” with respect to the output voltage Vx. For this reason, an additional connection between the two die is required so that the voltage Vx may be utilized as the ground voltage for the gate buffer of the high-side switch. The disadvantage of an extra connection may be outweighed by the higher frequency switching possible using MESFETs when compared to traditional silicon devices.

A second variation on the silicon Buck converter repartitions the two dice so that the PFM/PFM control is included in a first die and all other functions (including the BBM circuit, gate drive buffers, high and low-side switches) are included in a second die. Integrating the BBM circuit and gate drivers monolithically facilitates circuit methods to cancel the adverse impact of threshold variation in controlling the timing of the break-before-make interval. In other words, a shorter BBM time can be employed without risk of shoot-through. Only three interconnections are required to interconnect the two dice, namely V_{batt}, ground and the input to the BBM circuit. In this partitioning, no power parasitics are present. The monolithic construction of the switches, buffers and PFM/PWM circuit makes the use of non-silicon implementations (such as MESFET) problematic.

Another example of an innovative multi-die semiconductor product that uses the PBOL technique is a boost converter that includes a control die and a separate die for a discrete Schottky diode rectifier. The control die includes a PWM/PFM control circuit, gate buffers as well as high and low-side switches. The two dice require four interconnections for V_{batt}, ground, feedback V_{FB}, and output Vₓ.

The buck and boost converters just described partition their functions between two dice. The two dice share a number of interconnections, some of which are also connected to external components. For example, in each of the examples, both dice are connected to the battery voltage V_{batt} and ground. In several implementations, both dice share a connection for the output voltage Vx. When the PBOL method is used, these converters are advantageously implemented in a configuration that places one die above and one die below the leadframe. The two dice are configures so that common interconnections (e.g., V_{BATT}, Vₓ. and ground) may be bump connected to the same lead.

Implementations that combine PBOL connected dice with wire bond connected dice can also be used to produce a range of novel semiconductor products. For one such example, a vertical power MOSFET device and a parallel Schottky diode are combined in a single package. The MOSFET is attached using wire bonding techniques and the Schottky is bumped attached to the same leads. Similarly, by combining an N-channel MOSFET, P-channel MOSFET and Schottky diode, in a single package, a complementary half-bridge for use in synchronous Buck converters may be produced. In this particular implementation, the two MOSFETS are connected in series using wire bonds to the leadframe. The Schottky is pillar bump connected to the leadframe in parallel with the N-channel device.

The PBOL method may also be used to produce a novel protection circuit for one-cell lithium ion batteries implemented as two separate dice. Each dice includes an overcharge protection (OCP) trench powered MOSFET and an over discharge protection (ODCP) trench powered MOSFET. The two MOSFETS in each dice are connected in series—drain to drain. The two dice are positioned in the same package with one above and one below the leadframe. The PBOL method is used to connect to the two dice in parallel with the two OCP MOSFETS (one in each die) connected source to source and gate to gate and the two two ODCP MOSFETS (one in each die) connected source to source and gate to gate. The use of two die (and therefore, two OCP MOSFETS and two ODCP MOSFETS) means that the overall resistance of the safety switch is reduced in comparison with traditional single die implementations.

### BRIEF DESCRIPTION OF THE DRAWINGS

FIG. 1A is a cross-section of a PBOL (Pillar Bump-On-Leadframe) semiconductor product.

FIG. 1B is a detailed view of a pillar bump connecting a leadframe and semiconductor.

FIG. 2 is another detailed view of a pillar bump connecting a leadframe and semiconductor.

FIG. 3 is a cross-section of a stacked PBOL semiconductor product.

FIG. 4 is a cross-section of a combination PBOL and wirebond semiconductor product.

FIG. 5 is a cross-section of a gullwing PBOL (Pillar Bump-On-Leadframe) semiconductor product.

FIG. 6 is a cross-section of a flatpack PBOL (Pillar Bump-On-Leadframe) semiconductor product.

### DETAILED DESCRIPTION OF THE PREFERRED EMBODIMENTS

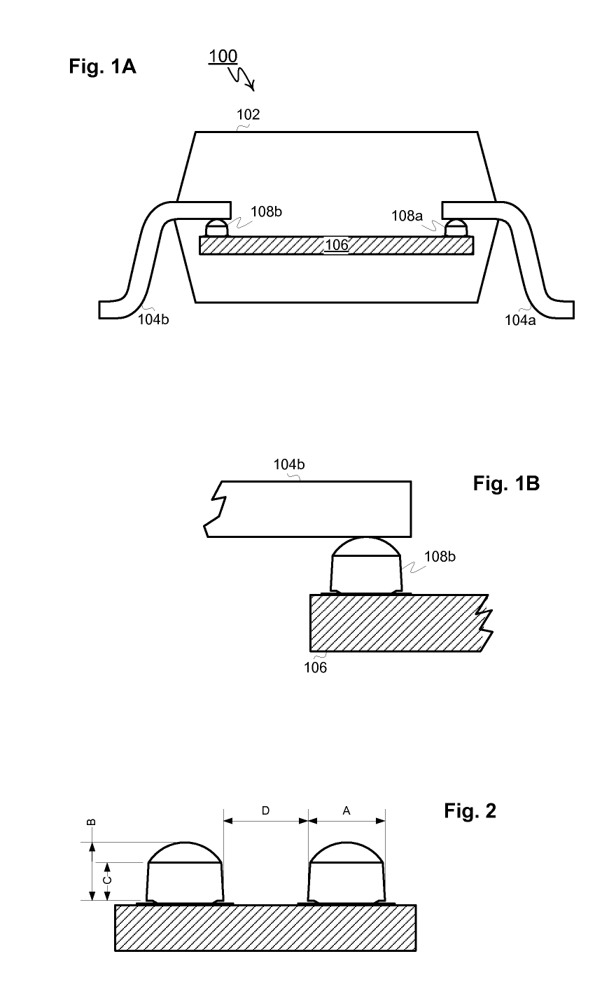

This document discloses a method for interconnecting semiconductor products to their leadframes using pillar bumps. As shown in FIG. 1A, a representative semiconductor product 100 that uses this method includes an injection molded plastic package 102 that surrounds leads 104A and 104B, a semiconductor dice 106 and conducting pillar bumps 108A and 108B. The pillar bumps serve both as the mechanical support for the die during assembly and as an electrical connection to the die, and therefore should ideally exhibit low thermal and electrical resistance. In a preferred embodiment shown more clearly in FIG. 1B, the conductive pillar bump includes a substantially cylindrical base which may or may not be tapered and is typically made from a conductive material such as copper. The base section is connected to the surface of the semiconductor dice. The second end of the base (i.e., the end not connected to the dice) is a soft metal ball or cap typically made of solder.

As shown in FIG. 2, each pillar bump is typically on the order of 140 microns in width (dimension A) and 100 microns in height (dimension B). The base portion is typically 60 microns in height (dimension C) and the bump portion is 35 microns high. Adjacent pillar bumps are spaced 300 microns or more apart (dimension D). Of course, each of the preceding dimensions is intended to be representative in nature and other values may be used for differing implementations.

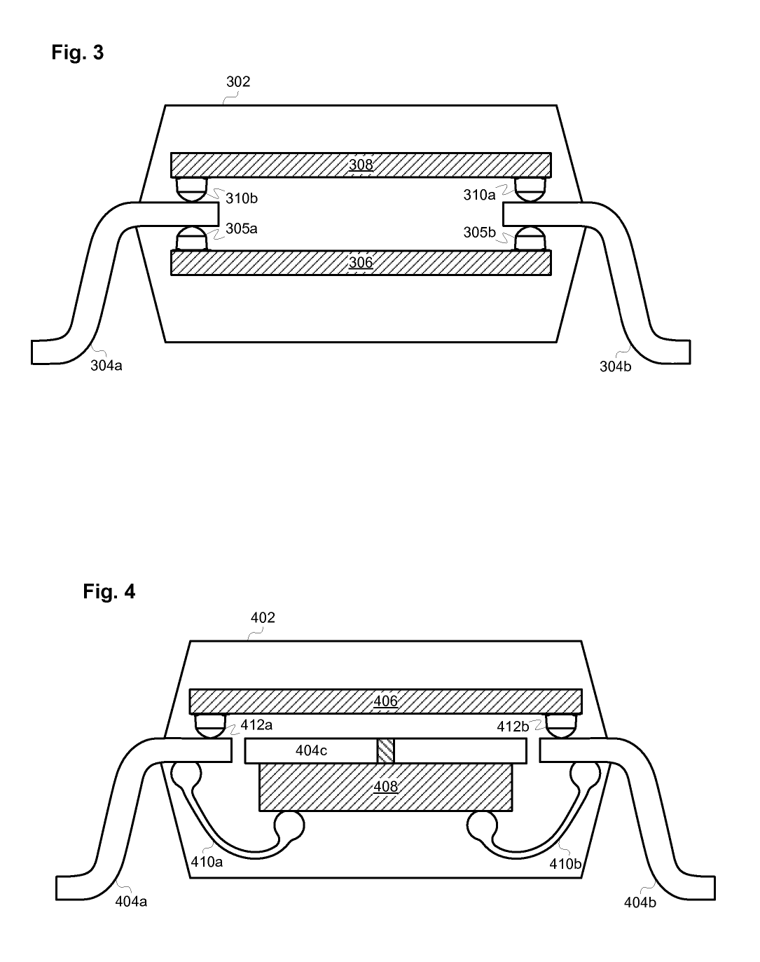

The pillar bump interconnection method may be used for a wide range of differing semiconductor products. In FIG. 1, the pillar bump method is used for an implementation where the leads extend over the semiconductor dice. It is equally practical to produce products in which the dice extends over the leads. Alternately, as shown in FIG. 3, two dice may be used—one under and one over the leads.

FIG. 4 shows another variation that also includes two dice. In this case, however one device is connected using pillar bumps and the other is connected using traditional wire bonds. It may be appreciated that the two dice in FIG. 4 may be repositioned with the wirebonded dice on top and the pillar bump attached dice underneath.

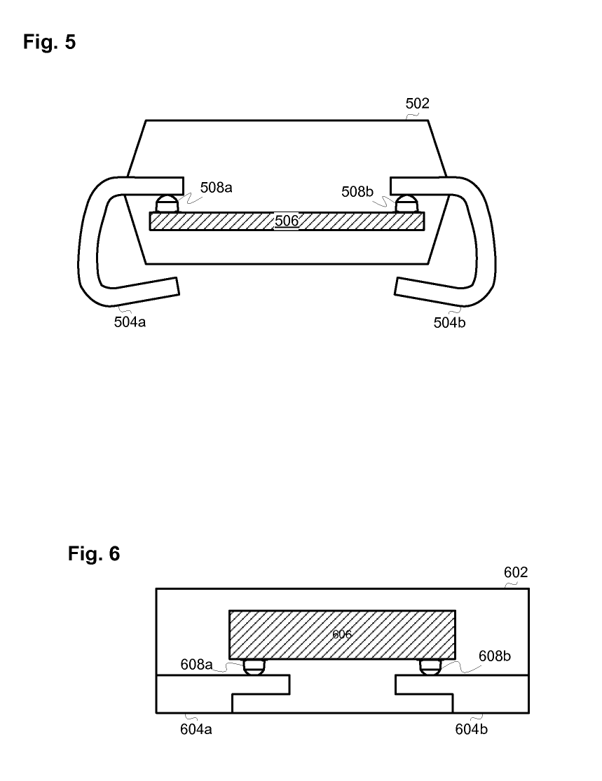

FIGS. 5 and 6 show semiconductor products that use the pillar bump method for interconnection. In FIG. 5, a gullwing package is shown and in FIG. 6 a flat package is shown. In each case, single or multiple dice may be used with pillar bump interconnection or any combination of pillar bump and wire bond interconnections.

Compared to the bump on leadframe method, the pillar bump method offers the following advantages:
1) Copper pillar has fine pitch capability of 80 um and below;
2) Bump height control or coplanarity is better (or more accurate).
3) Copper pillar allows easier flow of mold compound (or underfill) between bumps, minimizing molding voids in molded packages.
4) Copper has better thermal resistance than Solder—better heat dissipation.
5) Copper pillar can make pillar bar (i.e. elongated bump) to reduce contact resistance for both thermal and electrical performance.
6) Copper pillar bump can have less current crowding, reduced local Joule heating, longer bump life (better reliability), and increase current density/capability.
7) Copper does not have Tin (Solder) whisker reliability issue.

In general, it should be appreciated that the present invention is specifically intended to cover the specific embodiments shown in the accompanying figures. In addition, the present invention specifically includes modification of all of the embodiments shown in U.S. patent application Ser. No. 11/381,292 to replace the disclosed bump on leadframe with the pillar bump on leadframe method of the present invention.

What is claimed is:

1. An integrated circuit product that includes:
a first semiconductor die,
a first lead, the first lead connected to the first semiconductor die by a first electrically conductive pillar bump where the pillar bump includes a substantially cylindrical base section connected to the first semiconductor die and a bump portion in contact with the first lead; and
a package containing the first semiconductor die, the first electrically conductive pillar bump and a portion of the first lead.

2. An integrated circuit product as recited in claim 1 that further comprises a second semiconductor die, the second semiconductor die electrically connected to the first lead.

3. An integrated circuit product as recited in claim 2 in which the second semiconductor die is connected to the first lead by a wire.

4. An integrated circuit product as recited in claim 2 in which the second semiconductor die is connected to the first lead by a second electrically conductive pillar bump.

5. An integrated circuit product as recited in claim 2 in which the first and second semiconductor dice are stacked to substantially overlap each other.

6. An integrated circuit product as recited in claim 2 in which the first and second semiconductor dice are positioned adjacent to each other.

7. An integrated circuit product as recited in claim 2 in which the first semiconductor die includes a vertical power MOSFET and the second semiconductor die includes a Schottky diode.

8. An integrated circuit product in claim 2 in which the first semiconductor die includes a first MOSFET and the second semiconductor die includes a second MOSFET.

9. A method for manufacturing an integrated circuit product,
the method comprising:
fabricating a first semiconductor die;
forming a first electrically conductive pillar bump on the first semiconductor die where the a first electrically conductive pillar bump includes a substantially cylindrical base section connected to the first semiconductor die and a bump portion; and
positioning a leadframe in contact with the bump portion of the first electrically conductive pillar bump.

10. A method as recited in claim 9 that further comprises:
fabricating a second semiconductor die;
forming a second electrically conductive pillar bump on the second semiconductor die; and
positioning the leadframe in contact with the bump portion of the second electrically conductive pillar bump.

11. A method as recited in claim 10 in which the first and second semiconductor dice are stacked to substantially overlap each other.

11. A method as recited in claim 10 in which the first semiconductor die includes a vertical power MOSFET and the second semiconductor die includes a Schottky diode.

12. A method as recited in claim 10 in which the first semiconductor die includes a first MOSFET and the second semiconductor die includes a second MOSFET.
